(19) United States
(12) Patent Application Publication
(10) Pub. No.: US 2007/0131988 A1
(43) Pub. Date: Jun. 14, 2007

(54) CMOS image sensor devices and fabrication method thereof

(75) Inventor: Chin-Min Lin, Taichung (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/298,694

(22) Filed: Dec. 12, 2005

(51) Int. Cl. H01L 21/00; H01L 31/113

(52) U.S. Cl. 257/291; 257/292; 438/48

(57) ABSTRACT

CMOS image sensor devices and fabrication methods thereof. A CMOS image sensor device comprises an array of photo-sensing pixels in a first region of a substrate. Each photo-sensing pixel comprises a fully non-salicide transistor and a pinned photodiode. A logic circuit comprises a complementary metal oxide semiconductor (CMOS) transistor in a second region of the substrate, wherein a salicide is formed on the CMOS transistor in the second region but non-salicide is formed on the first region of the substrate.

### BACKGROUND

The invention relates to optical electronic devices, and more particularly, to complementary metal oxide semiconductor (CMOS) image sensor devices and fabrication methods thereof.

CMOS image sensor devices are used in a wide variety of applications, such as digital still camera (DSC) applications. These devices utilize an array of active pixels or image sensor cells, comprising photodiode elements, to collect photo energy for conversion of images to digital data streams.

For DSC applications, high-performance imaging with low crosstalk and noise, providing superior low-light performance is required.

Image sensor cells are usually comprised of active image sensing elements, such as photodiodes, in addition to adjacent transistor structures, such as transfer transistors and reset transistors. These transistor structures, as well as additional devices used for the control and signal circuits in the peripheral regions of the image sensor cells, or used for peripheral logic circuits, are comprised of complimentary metal oxide semiconductor (CMOS) devices. Therefore, to reduce process cost and complexity, image sensor cells have also been fabricated using the same CMOS process sequences used for the peripheral CMOS logic circuits. This approach, however, can influence the quality of the photodiode element of the image sensor cell, if the photodiode element is subjected to traditional CMOS process sequences. For example, if a metal silicide layer is formed on the surface of the photodiode element, during the formation of self-aligned metal silicide (salicide) on the gate structure, as well as on the source/drain region of the CMOS logic circuits, undesirable leakage, in the form of dark current generation, as well as degraded signal to noise (S/N) ratios, of the image sensor cell, can result.

U.S. Pat. No. 5,863,820, the entirety of which is hereby incorporated by reference, discloses a fabrication sequence for forming salicide only on elements of logic regions, while protecting regions of memory devices from the same salicide process. However this prior art does not teach the fabrication sequence, detailed in the present invention, in which a thin silicon oxide layer, and a thick organic layer, are patterned to allow salicide formation only on the top surface of a gate structure of an image sensor cell, while protecting the photodiode element of this cell from the same salicide formation procedure.

U.S. Pat. No. 6,194,258, the entirety of which is hereby incorporated by reference, discloses a method for integrating the formation of a salicide CMOS logic device, for a CMOS logic circuit region, and of a non-salicided photodiode element for an image sensor cell region. FIG. 1 is a cross-section of a conventional CMOS image sensor with salicide CMOS devices and a non-salicided photodiode element. The conventional CMOS image sensor comprises an image sensor cell region 70a and a CMOS logic region 80 on the P well region 2 of a semiconductor substrate 1. By selectively forming an additional thin silicon oxide layer 11 on the top surface of the photodiode element 9, formation of metal silicide on the photodiode element 9 can be prevented, during the procedure used to form the desired metal silicide layer 14 on the CMOS logic devices, thus allowing low dark current generation, and a high signal to noise ratio, to be obtained via the non-salicided, photodiode element.

The conventional method selectively forms a non-salicide area at S/D regions and a salicide at gate regions. Silicide gate regions, however, can be a metastable region. Metal elements can further diffuse into photodiode region during a subsequent high temperature process causing leakage spots in the photodiode, thereby deteriorating electrical performance as well as degrading signal to noise (S/N) ratios of the image sensor cell. Moreover, separately forming a non-salicide area at S/D regions and a salicide at a gate region requires lengthy and complicated processes, resulting in high production costs and narrow process windows.

### SUMMARY

CMOS image sensor devices with fully salicided CMOS devices for CMOS logic circuits and fully non-salicide transfer transistors and a pinned photodiode element of an image sensor cell are provided.

The invention provides a CMOS image sensor device comprising an array of photo-sensing pixels in a first region of a substrate. Each photo-sensing pixel comprises a fully non-salicide transistor and a pinned photodiode. A logic circuit comprises a complementary metal-oxide semiconductor (CMOS) transistor in a second region of the substrate, wherein a salicide is formed on the CMOS transistor in the second region but a fully non-salicide transfer transistor is formed on the first region of the substrate.

The invention also provides a CMOS image sensor device comprising an array of photo-sensing pixels in a main region of a substrate. Each photo-sensing pixel comprises a fully non-salicide transistor and a pinned photodiode, wherein the fully non-salicide transistor comprises a first gate structure with a width greater than 0.7 μm. A logic circuit comprises a complementary metal oxide semiconductor (CMOS) transistor in a peripheral region of the substrate, wherein a salicide is formed on the CMOS transistor in the peripheral region but fully non-silicide is formed on the main region of the substrate, and wherein the CMOS transistor comprises a second gate structure with a width less than 0.18 μm.

The invention further provides a method of fabricating a CMOS image sensor device. A P well region is formed in a top portion of a semiconductor substrate. A first gate structure is formed on a gate insulator layer on a first region of the semiconductor substrate to be used for an image sensor cell. A second gate structure is formed on the gate insulator layer on a second region of the semiconductor substrate to be used for a CMOS logic circuit region, wherein the first gate structure and the second gate structure are fabricated from different generations of lithography processes. A first source/drain region is formed in an area of the semiconductor substrate not covered by the first gate structure in the first region of the semiconductor substrate. A second source/drain region is formed in an area of the semiconductor substrate not covered by the second gate structure in the second region of the semiconductor substrate. A photodiode element comprised of an N type region in a portion of the P well region is formed in the first region of the semiconductor substrate. A thin silicon oxide layer is deposited on the first region of the semiconductor substrate. A metal silicide layer is formed on a top surface of the second gate structure, and on the second source/drain region in the second region of said semiconductor substrate.

### DESCRIPTION OF THE DRAWINGS

The invention can be more fully understood by reading the subsequent detailed description in conjunction with the examples and references made to the accompanying drawings, wherein:

FIG. 1 is a cross-section of a conventional CMOS image sensor device with salicide gate regions in CMOS devices and a non-salicided photodiode element;

FIGS. 2A-2F are cross-sections of an embodiment of an integrated fabrication process, used to simultaneously form salicided CMOS devices for CMOS logic circuits and a fully non-salicided image sensor cell;

FIG. 3 is a schematic view of an embodiment of a four-transistor (4T) cell of a CMOS image sensor of the invention;

FIG. 4 is a schematic diagram illustrating an embodiment of an image sensor array; and

FIG. 5 is a block diagram of an embodiment of an optical electronic device.

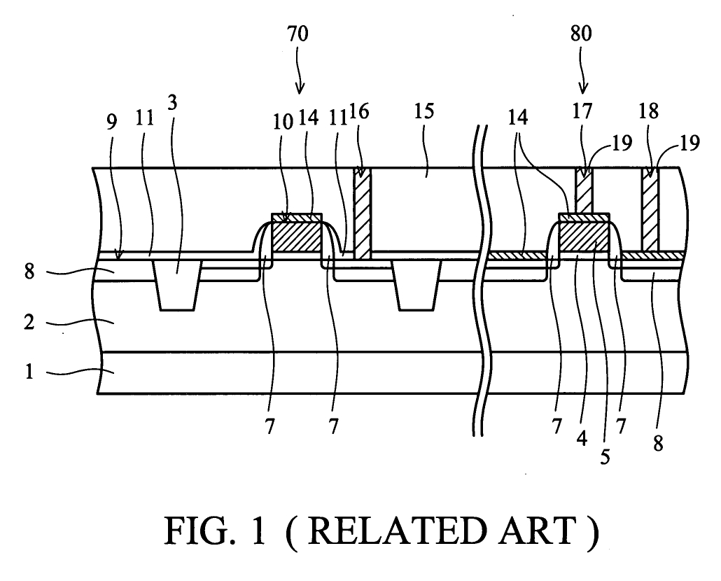

### DETAILED DESCRIPTION

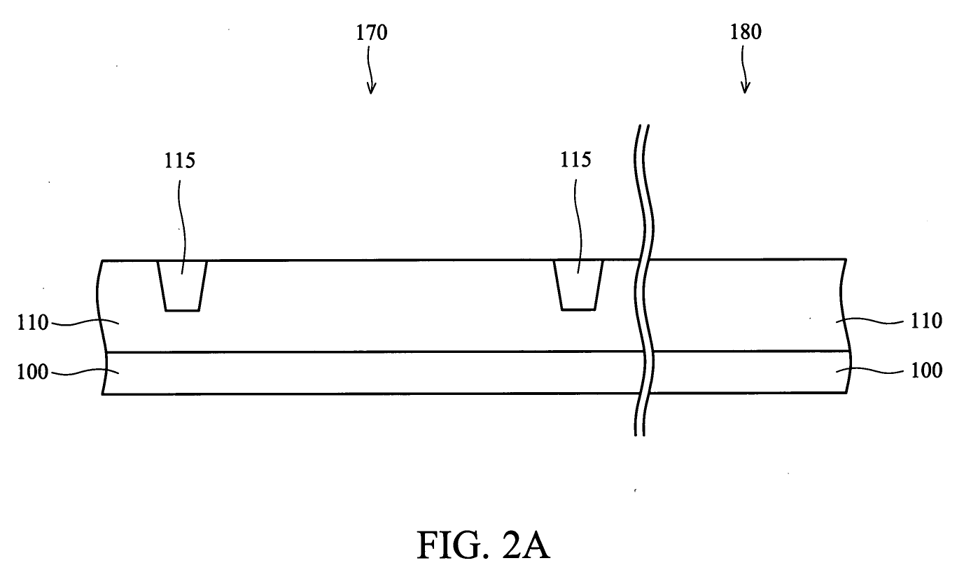

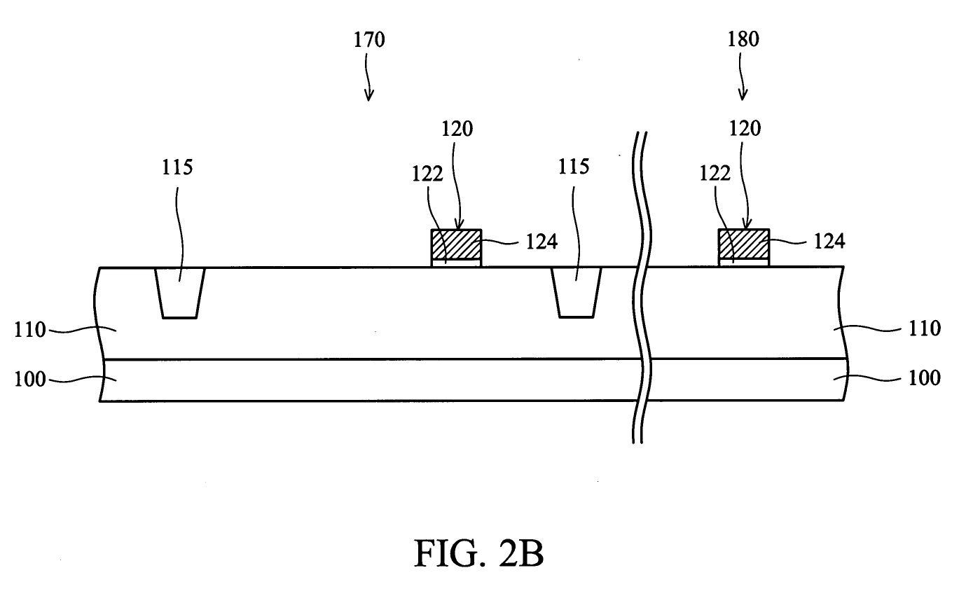

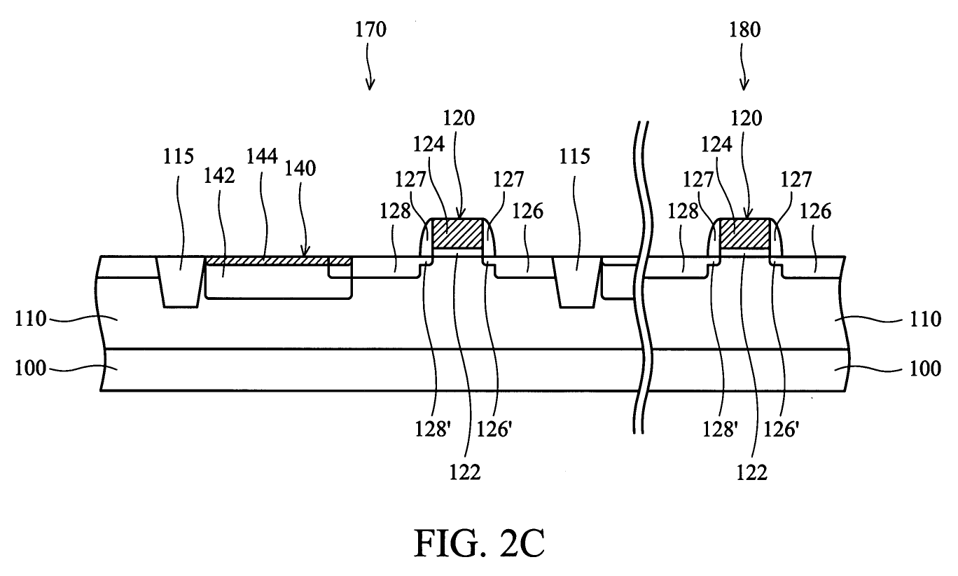

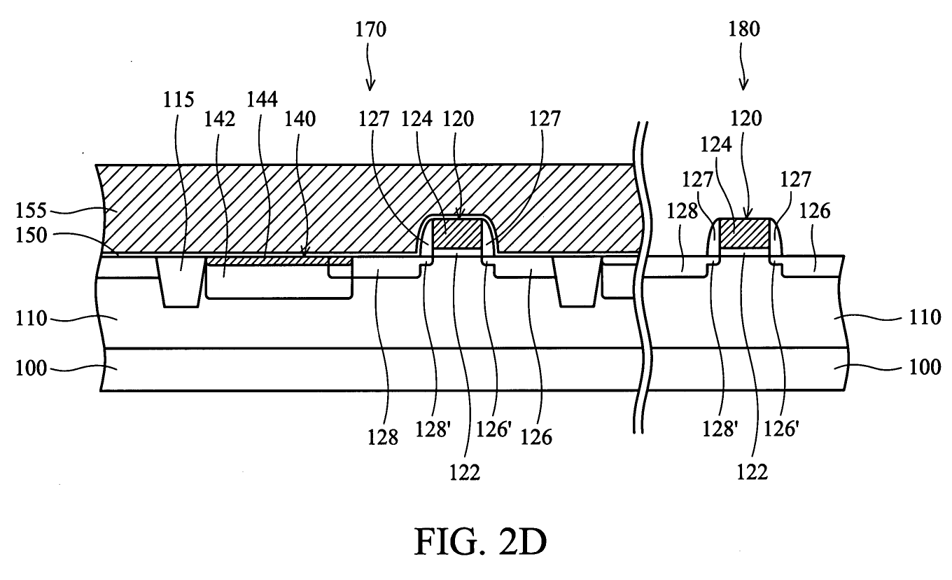

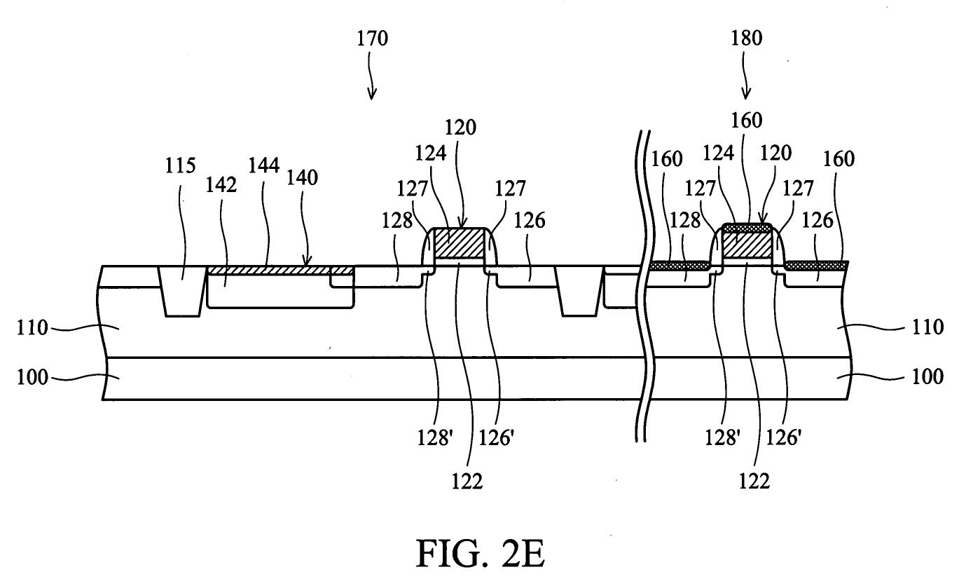

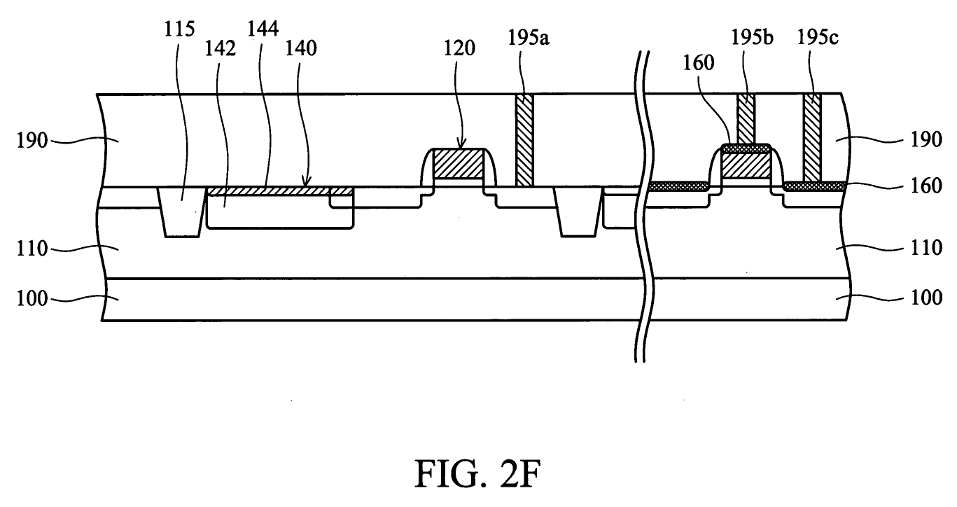

The process for integrating the fabrication of fully salicided CMOS devices for CMOS logic circuits and a fully non-salicide transfer transistor and a pinned photodiode element of an image sensor cell will now be described in detail. FIGS. 2A-2F are cross-sections of an embodiment of an integrated fabrication process, used to simultaneously form salicided CMOS devices for CMOS logic circuits and a fully non-salicided transfer transistor and a pinned photodiode element of an image sensor cell.

Referring to FIG. 2A, a P-type semiconductor substrate 100, such as a single crystalline silicon with a <100> crystallographic orientation, is provided. The P-type semiconductor substrate 100 comprises region 170 to be used for fabrication of the pixel or image sensor cell, and region 180 to be used for fabrication of complimentary metal oxide semiconductor (CMOS) logic circuits. P well region 110 is sequentially formed in a top portion of semiconductor substrate 100, via ion implantation of boron, at an implanting energy between about 140 to 250 KeV, and at a dose between about 2.5×10¹² to 3.0×10¹³ atoms/cm². The concentration of P type dopant in P well region 110 is greater than the concentration of P type dopant in semiconductor substrate 100. Isolation regions 115, either silicon oxide, shallow trench isolation (STI), or silicon dioxide, field oxide regions (FOX), are formed to electrically separate image sensor cell region 170 from CMOS logic circuit region 180 and electrically isolating the photodiode element.

Referring to FIG. 2B, polysilicon gate structures 120 for both the image sensor cell and for the CMOS logic circuits are formed on the P well region 110. Gate insulator layer 122, such as silicon dioxide, is thermally grown to a thickness between about 40 to 55 Å. A polysilicon layer is next deposited via low pressure chemical vapor deposition, (LPCVD), procedures to a thickness between about 1500 to 3000 Å. The polysilicon layer can be doped in situ, during deposition, via the addition of arsine, or phosphine, to a silane ambient, or the polysilicon layer can be deposited intrinsically, and subsequently doped via implantation of arsenic or phosphorous ions. Conventional photolithographic and reactive ion etching, (RIE), procedures, using C1₂ or SF₆ as an etchant, are used to etch polysilicon, defining polysilicon gate structures 124, on gate insulator layer 122, located in image sensor cell region 170, and in CMOS logic circuit region 180. The photoresist shapes (not shown) used to define polysilicon gate structures 124, are removed via plasma oxygen ashing and careful wet cleaning, with the wet clean cycle removing the regions of gate insulator layer 122, not covered by polysilicon gate structures 124.

Referring to FIG. 2C, lightly doped, N type source/drain regions 126′ and 128′, are next formed in areas of P well region 110, not covered by polysilicon gate structures 124, via implantation of arsenic or phosphorous ions, at an energy between about 35 to 50 KeV, at a dose between about 1×10¹⁴ to 6×10¹⁵ atoms/cm². A silicon nitride layer is next deposited via LPCVD or via plasma enhanced chemical vapor deposition, (PECVD), procedures, at a thickness between about 800 to 2000 Å, followed by a blanket, anisotropic RIE procedure, using CF₄ as an etchant, creating silicon nitride spacers 127, on the sides of polysilicon gate structures 124.

Another implantation procedure is then performed, using arsenic or phosphorous ions at an energy between about 35 to 50 KeV, at a dose between about 1×10¹⁴ to 6×10¹⁵ atoms/cm², to form heavily doped, N type source/drain regions 126 and 128, in areas of P well region 110, not covered by polysilicon gate structure 124, or by silicon nitride spacers 127. This ion implantation procedure also results in the formation of photodiode element 140, in image sensor cell region 170, with photodiode element 140, comprised of the heavily doped N type region 142, in P well region 110. The polysilicon gate structure 140, in image sensor cell region 170, serves as a transfer gate transistor or as a reset transistor for the image sensor cell.

Referring to FIG. 2D, the process sequence used to form salicide layers on CMOS logic devices, while preventing salicide formation on the surface of photodiode element 140, is now described. A thin silicon oxide layer 150, obtained using rapid process oxidation (RPO) or obtained via LPCVD or PECVD procedures, at a thickness between about 300 to 400 Å, is formed on the P-type semiconductor substrate. Photoresist shape 155 is next defined and used as a mask to remove thin silicon oxide layer 150, from all regions of logic circuit region 180. This is accomplished using a buffered hydrofluoric acid solution.

After removal of photoresist shape 155, via plasma oxygen ashing and careful wet cleaning, the thin silicon oxide layer 150 in the image sensor cell region 170 is exposed.

Referring to FIG. 2E, a metal layer, such as titanium, cobalt, or nickel, is next deposited via RF sputtering or physical vapor deposition (PVD) procedures to a thickness between about 200 to 500 Å. An anneal cycle, performed using conventional furnace procedures or using a rapid thermal anneal procedure, at a temperature between about 650 to 800° C., is employed to form metal silicide layer 160, such as titanium silicide, cobalt silicide, or nickel silicide, on the exposed polysilicon or silicon surfaces on the peripheral CMOS logic circuit region 180, leaving unreacted metal on the thin silicon oxide layer 150 which overlays the transfer transistor or reset transistor and the photodiode element 140 in the image sensor cell region 170. The unreacted metal is then removed using a solution comprised of H₂SO₄—H₂O₂—NH₄OH, resulting in the desired performance enhancement, salicided elements in CMOS logic circuit region 180 and the fully non-salicided transfer transistor or reset transistor and the photodiode element in image sensor cell region 170, which results in less leakage current generation, and a larger signal to noise ratio, than counterparts fabricated with salicided photodiode elements.

Referring to FIG. 2F, an interlevel dielectric, (ILD), layer 190, such as silicon oxide or borophosphosilicate glass (BPSG), is next deposited, via LPCVD or PECVD procedures to a thickness between about 8000 to 13000 Å. A chemical mechanical polishing, (CMP), procedure is used for planarization purposes, creating a smooth top surface topography for ILD layer 190. Conventional photolithographic and RIE procedures, using CHF₃ as an etchant, are used to open contact hole 195a, in ILD layer 190, exposing a portion of the top surface of heavily doped, N type source/drain regions 126 and 128, in the image sensor cell region 170. The same photolithographic and RIE procedure also opens contact holes 195b and 195c, in ILD layer 190, exposing a portion of the top surface of metal silicide layer 160, located overlying the polysilicon gate structure, and the heavily doped, N type, source/drain region, located in CMOS logic circuit region 180. After removal of the photoresist shape used for definition of contact holes 195a, 195b, and 195c, via plasma oxygen ashing and careful wet cleaning, a metal layer such as tungsten, aluminum, or copper, is deposited via RF sputtering, or via plasma vapor deposition procedures, to a thickness between about 3500 to 5000 Å, completely filling contact holes 195a, 195b, and 195c. Removal of metal, from the top surface of ILD layer 190, is accomplished using either a CMP procedure, or via a selective RIE procedure, using Cl₂ or SF₆ as an etchant, creating metal contact plugs, in contact holes 195a, 195b, and 195c.

The ability to prevent salicide formation on the surface of the photodiode element, allows the dark generation, and signal to noise ratio, of the image sensor cell to be optimized, while this integrated process sequence allows the performance of the CMOS logic devices to be maximized with the inclusion of salicided CMOS devices, in the CMOS logic circuit region.

To reduce process cost and complexity, the image sensor cell can be fabricated using the same CMOS process sequences used for the peripheral CMOS logic circuits. Alternatively, the image sensor cell can be fabricated using different generation CMOS process sequences from the peripheral CMOS logic circuits. For example, the transfer transistor or reset transistor in the image sensor cell is fabricated using a CMOS process greater than 0.7 μm generation to gain more photo charge generation, while the peripheral CMOS logic circuits are fabricated using a CMOS process greater than the 0.18 μm generation. Since the CMOS image device region is formed by a fully non-salicide process, a least one lithographic step can be omitted, thereby reducing mask cost.

The invention provides CMOS image sensor devices comprising a photodiode, such as a pinned photodiode, adjacent to a transfer transistor in the image sensor cell region. The pinned photodiode can preferably comprise a shallow P—N junction adjacent to the transfer transistor, as shown in FIG. 2F. The photodiode consists of an approximately 0.2 μm deep P (or P⁺) implant 144 that cover the N-cathode diffusion 142. The N-cathode diffusion 142 extends to a depth of approximately 0.6 μm, and appears to be the same implant as that used for the N⁺ S/D contact diffusions 128. It extends slightly past the right end of the P-implant, and extends towards the surface to connect to the drain of the transfer transistor.

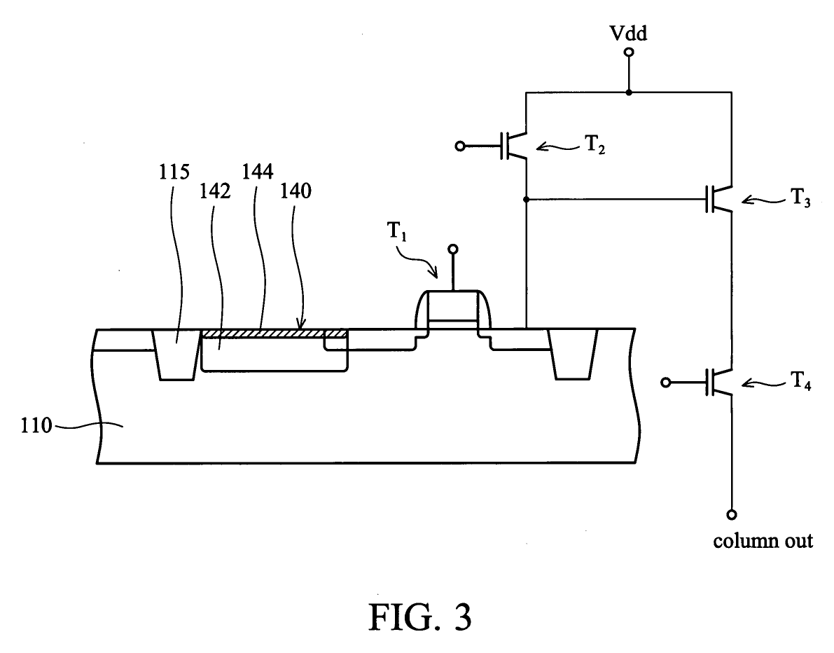

FIG. 3 is a schematic view of an embodiment of a four-transistor (4T) cell of a CMOS image sensor of the invention. The transfer transistor T₁ is used to connect the photodiode to the source follower transistor T₃ and to the V_{dd} bus through the reset transistor T₂. The gate of the transistor T₃ is connected by a first metal interconnect to the N⁺ diffusion between the two transistors T₁ and T₂. This reduces the effects of the leakage current associated with the source follower gate contact of T3 to the pixel cathode. The transistor T₄ is used to read the pixel voltage on the column out line.

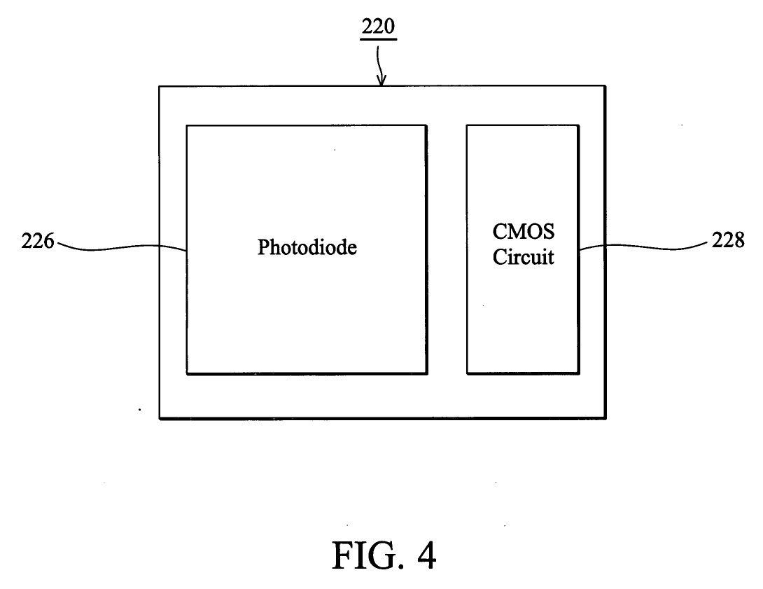

It is appreciated some embodiments of the CMOS image sensor are directed to an electronic device for digital still camera (DSC) applications. In FIG.4, an image sensor device 200 comprises an array of pixels 220. Each pixel 220 comprises a photodiode 226 and a CMOS circuit 228, as shown in FIG. 4.

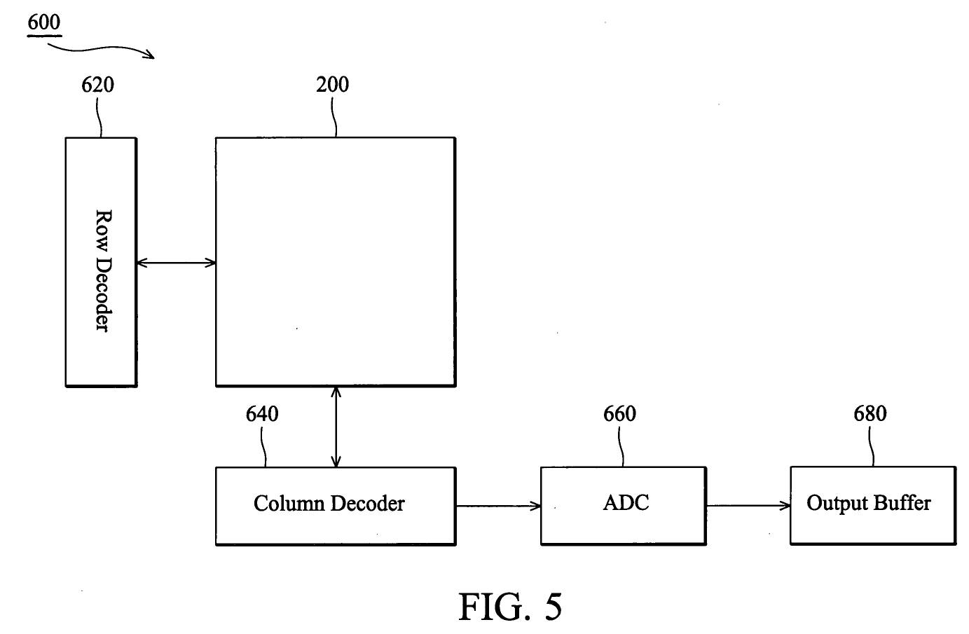

Image sensor device 200 can be easily integrated with other control units, such as a row decoder and a column decoder, an analog to digital converter (ADC), and a digital signal processor to form a system on a silicon chip. FIG. 5 shows a block diagram illustrating an embodiment of an electronic device 600. The electronic device 600 comprises an image sensor device configured to receive an optical image and generate an electrical analog signal representing the image. A row decoder 620 and a column decoder 640 are used to address any one or multiple pixels and retrieve data from selected pixels. An ADC 660 is coupled to column decoder 640 to receive the analog signal and convert the analog signal into a digital signal. An output buffer 680 is connected to ADC to store digital signal converted by the ADC.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A CMOS image sensor device comprising:
an array of photo-sensing pixels in a first region of a substrate, each photo-sensing pixel comprising a fully non-salicide transistor and a pinned photodiode; and
a logic circuit comprising a complementary metal oxide semiconductor (CMOS) transistor in a second region of the substrate, wherein a salicide is formed on the CMOS transistor in the second region but non-salicide is formed on the first region of the substrate.

2. The CMOS image sensor device as claimed in claim 1, wherein each photo-sensing pixel comprises four transistors electrically operating corresponding to the pinned photodiode.

3. The CMOS image sensor device as claimed in claim 1, further comprising a P well region in top portion of the substrate.

4. The CMOS image sensor device as claimed in claim 1, wherein the fully non-salicide transistor in the first region comprises a first gate structure, and the CMOS transistor in the second region comprises a second gate structure.

5. The CMOS image sensor device as claimed in claim 4, wherein the width of the first gate structure is greater than the width of the second gate structure.

6. The CMOS image sensor device as claimed in claim 4, wherein the first gate structure is fabricated to have a width greater than 0.7 μm, while the second gate structure is fabricated to have a width less than 0.13 μm.

7. The CMOS image sensor device as claimed in claim 1, wherein the salicide is formed on a second gate structure, and source/drain regions of the CMOS transistor in the second region.

8. The CMOS image sensor device as claimed in claim 1, wherein the pinned photodiode comprises a deep implant region overlying a p-n photodiode element.

9. A CMOS image sensor device comprising:
an array of photo-sensing pixels in a main region of a substrate, each photo-sensing pixel comprising a fully non-salicide transistor and a pinned photodiode, wherein the fully non-salicide transistor comprises a first gate structure with a width greater than 0.7 μm; and
a logic circuit comprising a complementary metal oxide semiconductor (CMOS) transistor in a peripheral region of the substrate, wherein a salicide is formed on the CMOS transistor in the peripheral region but fully non-silicide is formed on the main region of the substrate, and wherein the CMOS transistor comprises a second gate structure with a width less than 0.18 μm.

10. The CMOS image sensor device as claimed in claim 9, wherein each photo-sensing pixel comprises four transistors electrically coupled to the pinned photodiode.

11. The CMOS image sensor device as claimed in claim 9, wherein the salicide is formed on a second gate structure, and source/drain regions of the CMOS transistor in the peripheral region.

12. The CMOS image sensor device as claimed in claim 9, wherein the pinned photodiode comprises a deep implant region overlying a p-n photodiode.

13. The CMOS image sensor device as claimed in claim 9, wherein the first gate structure and the second gate structure are fabricated from different generations of lithography processes.

14. An optical electronic device comprising:
a CMOS image sensor device as claimed in claim 1, responsive to an optical image, producing an analog electrical representation of the optical image;
a row decoder and a column decoder coupled to the CMOS image sensor device respectively to address one or multiple pixels and to retrieve data from selected pixels;
an analog-to-digital converter (ADC) coupled to the column decoder, operating to convert the analog electrical representation into a digital image; and
an output buffer configured to store digital image data converted by the analog-to-digital converter.

15. A method of fabricating a CMOS image sensor device, comprising:
forming a P well region in a top portion of a semiconductor substrate;
forming a first gate structure on a gate insulator layer on a first region of the semiconductor substrate to be used for an image sensor cell;
forming a second gate structure on the gate insulator layer on a second region of the semiconductor substrate to be used for a CMOS logic circuit region, wherein the first gate structure and the second gate structure are fabricated from different generations of lithography processes;
forming a first source/drain region in an area of the semiconductor substrate not covered by the first gate structure in the first region of the semiconductor substrate, and forming a second source/drain region in an area of the semiconductor substrate not covered by the second gate structure in the second region of the semiconductor substrate;
forming a photodiode element comprised of an N type region in a portion of the P well region located in the first region of the semiconductor substrate;
depositing a thin silicon oxide layer on the first region of the semiconductor substrate; and
forming a metal silicide layer on a top surface of the second gate structure, and on the second source/drain region in the second region of said semiconductor substrate.

16. The method of fabricating a CMOS image sensor device as claimed in claim 15, the first gate structure is fabricated to have a width greater than 0.7 μm, while the second gate structure is fabricated to have a width less than 0.13 μm.

17. The method of fabricating a CMOS image sensor device as claimed in claim 15, wherein said gate insulator layer is a silicon dioxide layer, obtained via thermal oxidation procedures, at a thickness between about 40 to 55 Å.

18. The method of fabricating a CMOS image sensor device as claimed in claim 15, wherein said first gate structure, and said second gate structure, are defined from a polysilicon layer, which is obtained via LPCVD procedures at a thickness between about 1500 to 3000 Å, and either doped in situ, during deposition via an addition of arsine, or phosphine, to a silane ambient, or deposited intrinsically then doped via implantation of arsenic, or phosphorous ions.

19. The method of fabricating a CMOS image sensor device as claimed in claim 15, wherein the metal silicide layer is a titanium silicide layer, a cobalt silicide layer, or a nickel silicide layer.

20. The method of fabricating a CMOS image sensor device as claimed in claim 15, further comprising forming a deep implant region overlying the photodiode element.
